(19) United States
(12) Patent Application Publication
(10) Pub. No.: US 2015/0116261 A1
(43) Pub. Date: Apr. 30, 2015

(54) TOUCH DETECTION APPARATUS HAVING FUNCTION FOR CONTROLLING PARASITIC CAPACITANCE, AND TOUCH DETECTION METHOD

(71) Applicant: IP CITY CO., LTD., Seoul (KR)

(72) Inventor: Byung Cik Ahn, Gyeonggi-do (KR)

(73) Assignee: IP CITY CO., LTD., Seoul (KR)

(21) Appl. No.: 14/405,388

(22) PCT Filed: Jun. 4, 2013
(86) PCT No.: PCT/KR2013/004939

§ 371 Date: Dec. 3, 2014

(30) Foreign Application Priority Data
Jun. 4, 2012 (KR) 10-2012-0060010
Sep. 7, 2012 (KR) 10-2012-0099176
Dec. 26, 2012 (KR) 10-2012-0153871
Mar. 7, 2013 (KR) 10-2013-0024590

(51) Int. Cl. G06F 3/041; G06F 3/044; G01R 27/26

(52) U.S. Cl. CPC G06F 3/0418; G01R 27/2605; G01R 27/2688; G06F 3/044
USPC 345/174

(57) ABSTRACT

According to one embodiment of the present invention, a touch detection apparatus for a touch panel, including a plurality of sensor pads and signal wires connected to the plurality of sensor pads, respectively, is provided. The touch detection apparatus comprises a parasitic capacitance control unit for controlling the parasitic capacitance generated between a specific sensor pad which is to be an object of touch detection from among the plurality of sensor pads and another adjacent sensor pad. The parasitic capacitance control unit enables the output voltage of the specific sensor pad to be applied to another sensor pad connected to the signal wire that is adjacent to the signal wire of the specific sensor pad.

### TECHNICAL FIELD

The present invention relates to a touch detection apparatus, and more particularly, to a touch detection apparatus in which parasitic capacitance is reduced by applying an output voltage of a sensor pad that detects a touch to another adjacent sensor pad.

### BACKGROUND ART

The touch screen panel is a device in which user commands are input by contacting text or diagrams displayed on a screen of the image display device using a finger of a person or other contact means, and thus the touch screen panel is attached on the image display device. The touch screen panel converts a contact position which is contacted by the finger of the person, or the like into an electrical signal, and then uses the converted electrical signal as an input signal.

Methods of implementing the touch screen panel include a resistance layer method, an optical detection method, a capacitive method, etc. The touch panel using the capacitive method converts the contact position into the electrical signal by detecting a change of capacitance which is formed by a conductive detection pattern with another detection pattern, ground electrode, or the like.

FIG. 1 is an exploded plan view showing an example of a capacitive touch screen panel according to a conventional technique.

Referring to FIG. 1, a touch screen panel 10 includes a transparent substrate 12, a first sensor pattern layer 13, a first insulating layer 14, a second sensor pattern layer 15, and a second insulating layer 16, which are sequentially formed on the transparent substrate 12, and a metal wire 17.

The first sensor pattern layer 13 may be connected on the transparent substrate 12 along a lateral direction and to the metal wire 17 in a row unit.

The second sensor pattern layer 15 may be connected on the first insulating layer 14 along a column direction and alternately disposed with the first sensor pattern layer 13 so as not to overlap the first sensor pattern layer 13. Further the second sensor pattern layer 15 is connected to the metal wire 17 in a column unit.

When a finger of the person or a contact means contacts the touch screen panel 10, a change of capacitance according to a contact position is transferred to a driving circuit through the first and second sensor pattern layers 13 and 15 and the metal wire 17. The transferred change of the capacitance is converted into an electrical signal and thus the contact position is identified.

However, in the touch screen panel 10, since a pattern including a transparent conductive material such as indium tin oxide (ITO) should be separately included in the first and second sensor pattern layers 13 and 15 and the first insulating layer 14 should be included between the first and second sensor pattern layers 13 and 15, a thickness of the touch screen panel 10 is increased.

Further, since touch detection is possible when several changes of the capacitance finely generated by the touch are accumulated, the change of the capacitance should be detected at a high frequency. In order to accumulate enough the change of the capacitance in a predetermined time, a metal wire for maintaining a low resistance is needed. The metal wire makes a bezel on a border of the touch screen thick and causes an additional mask process.

In order to solve this problem, a touch detection apparatus has been proposed as shown in FIG. 2.

The touch detection apparatus shown in FIG. 2 includes a touch panel 20, a driving device 30, and a circuit substrate 40 which connects the touch panel 20 and the driving device 30.

The touch panel 20 is formed on a substrate 21, and includes a plurality of sensor pads 22 which are arranged in a matrix form of polygons and a plurality of signal wires 23 which are connected to the sensor pads 22.

An end of each signal wire 23 is connected to the sensor pad 22 and another end thereof is stretched to a lower edge of the substrate 21. The sensor pad 22 and the signal wire 23 may be patterned on a cover glass 50.

The driving device 30 sequentially selects one sensor pad 22 from the plurality of sensor pads 22, measures capacitance of the corresponding sensor pad 22 and thus detects whether the touch has occurred or not through the capacitance.

Since the plurality of sensor pads 22 are formed of a conductor and a distance between the sensor pads 22 is very small, parasitic capacitance is naturally present. The parasitic capacitance adversely affects the detection as to whether the touch has occurred or not.

Therefore, a technique for preventing errors of touch detection is required by minimizing the parasitic capacitance.

### DISCLOSURE

### Technical Problem

The present invention is directed to providing a touch detection apparatus including a plurality of sensor pads in which sensitivity of the touch detection is improved by controlling parasitic capacitance generated by a relation between the sensor pads.

### Technical Solution

One aspect of the present invention provides a touch detection apparatus for a touch panel, including a plurality of sensor pads and signal wires connected to the plurality of sensor pads, respectively, including: a parasitic capacitance control unit configured to control the parasitic capacitance generated between a specific sensor pad which is to be an object of touch detection from among the plurality of sensor pads and another adjacent sensor pad, and the parasitic capacitance control unit enables the output voltage of the specific sensor pad to be applied to another sensor pad connected to the signal wire that is adjacent to the signal wire of the specific sensor pad.

The parasitic capacitance control unit may enable an output voltage of the specific sensor pad to be applied to another sensor pad when the specific sensor pad is detected.

The parasitic capacitance control unit may include a buffer, and an input end of the buffer is connected to an output end of the specific sensor pad and an output end of the buffer is connected to another sensor pad, respectively.

The parasitic capacitance control unit may enable one of the output voltages of the specific sensor pad, which are detected from a first frame and a second frame to be selectively applied to another sensor pad in the second frame.

The parasitic capacitance control unit may include a buffer and a multiplexer, and an input end of the buffer may be connected to an output end of the specific sensor pad, an output end of the buffer may be connected to an input end of the multiplexer, and an output end of the multiplexer may be connected to another sensor pad, respectively.

The parasitic capacitance control unit may select one of the output voltages of the specific sensor pad, which are detected from the first frame and the second frame, and enable the selected output voltage to be applied to another sensor pad.

The parasitic capacitance control unit may enable the output voltage of the specific sensor pad to be applied to another sensor pad in the first frame when the first frame is an initial frame.

The parasitic capacitance control unit may enable the output voltage of the specific sensor pad to be applied to another sensor pad in the second frame when the output voltage of the specific sensor pad detected from the second frame is greater than a reference value for detecting the touch.

The plurality of sensor pads may be disposed in row and column directions and a dummy line may be formed between columns to suppress generation of parasitic capacitance according to a relation between sensor pads included in adjacent columns disposed in the column direction.

The plurality of sensor pads may have the greater area, the farther from a driving device which drives the sensor pads.

Another aspect of the present invention provides a touch detection method of a touch panel, including a plurality of sensor pads and signal wires connected to the plurality of sensor pads, respectively, including: controlling the parasitic capacitance so that the output voltage of the specific sensor pad which is to be an object of touch detection from among the plurality of sensor pads to be applied to another sensor pad connected to the signal wire that is adjacent to the signal wire of the specific sensor pad; and detecting the touch based on a change difference of an output voltage of the specific sensor pad, and the attenuation enables the output voltage of the specific sensor pad to be applied to another sensor pad having a signal wire that is adjacent to the signal wire of the specific sensor pad when the specific sensor pad is detected.

The controlling of the parasitic capacitance may include enabling output voltage of the specific sensor pad to be applied to another sensor pad when the specific sensor pad is detected.

The controlling of the parasitic capacitance may include selectively enabling one of the output voltages of the specific sensor pad, which are detected from a first frame and a second frame to be applied to another sensor pad in the second frame.

The controlling of the parasitic capacitance may include enabling the output voltage of the specific sensor pad to be applied to another sensor pad in the first frame when the first frame is an initial frame.

The controlling of the parasitic capacitance may include enabling the output voltage of the specific sensor pad to be applied to another sensor pad in the second frame when the output voltage of the specific sensor pad detected from the second frame is greater than a reference value for detecting the touch.

### Advantageous Effects

According to the embodiment of the present invention, the touch detection apparatus including a plurality of sensor pads in which as an output voltage of a sensor pad which is to be an object of touch detection is applied to another adjacent sensor pad, parasitic capacitance can be reduced, and thus touch sensitivity can be improved.

Further, according to the embodiment of the present invention, the touch detection apparatus including a plurality of sensor pads in which as an output voltage of a sensor pad which is detected in a first frame and is to be an object of touch detection, is applied to another sensor pad when touch detection is performed in a second frame, parasitic capacitance can be controlled, and thus touch sensitivity can be improved.

Meanwhile, according to the embodiment of the present invention, the touch detection apparatus including a plurality of sensor pads in which as a dummy line is formed between columns of the sensor pad, parasitic capacitance can be further reduced.

Effects of the present invention are not limited to the above described effects, and it should be understood that all possible effects deduced from a configuration of the present invention described in detailed descriptions and the claims are included.

### DESCRIPTION OF DRAWINGS

FIG. 1 is an exploded plan view showing an example of a capacitive touch screen panel according to a conventional technique.

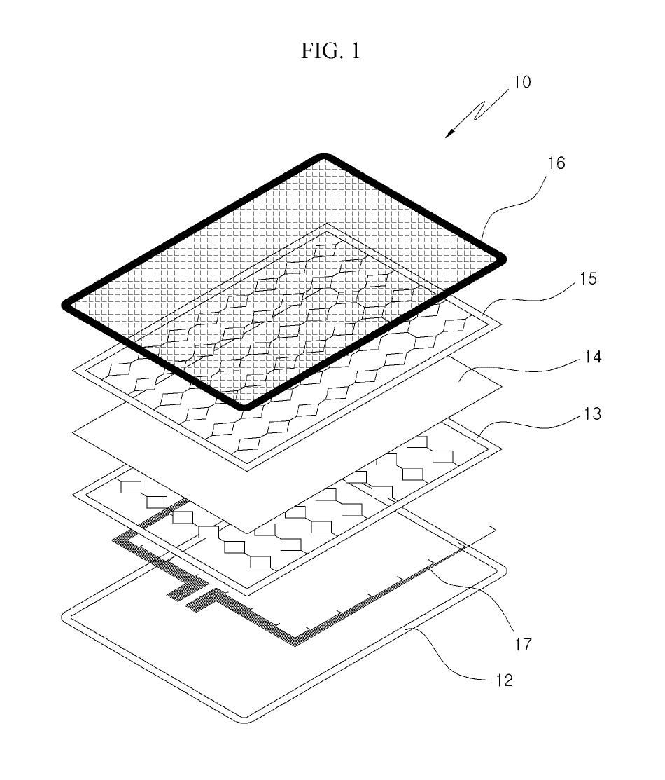

FIG. 2 is an exploded plan view of a traditional touch detection apparatus.

FIG. 3 is a view showing a structure of a touch detection apparatus according to an exemplary embodiment of the present invention.

FIG. 4 is a circuit diagram illustrating a touch detection unit according to an exemplary embodiment of the present invention.

FIG. 5 is a waveform diagram illustrating a touch detection unit according to an exemplary embodiment of the present invention.

FIG. 6 is a view showing a touch detection apparatus according to an exemplary embodiment of the present invention.

FIG. 7 is a view showing n sensor pads included in a column.

FIG. 8 is a view showing an example of an arrangement of sensor pads and signal wires.

FIG. 9 is a simple circuit diagram of a touch detection apparatus according to another exemplary embodiment of the present invention.

FIG. 10 is a view showing a touch detection apparatus according to another exemplary embodiment of the present invention.

FIG. 11 is a view showing n sensor pads included in a column.

FIG. 12 is a view showing a parasitic capacitance control unit of a touch detection apparatus according to another exemplary embodiment of the present invention.

FIG. 13 is a simple circuit diagram of a touch detection apparatus according to another exemplary embodiment of the present invention.

FIG. 14 is a view showing an example of a dummy line formed according to an exemplary embodiment of the present invention.

FIG. 15 is a view showing a configuration of a touch detection apparatus according to an exemplary embodiment of the present invention.

### MODES OF THE INVENTION

Exemplary embodiments of the present invention will be described in detail below with reference to the accompanying drawings. However, the present invention may be made in many different forms, and thus the present invention is not limited to the above-described embodiments. Further, detailed descriptions of well-known functions or configurations that unnecessarily obscure the gist of the invention in the following explanations and accompanying drawings will be omitted for a more precise description, and the same reference numbers will be used throughout this specification to refer to the same or like parts.

Throughout this specification, when an element is referred to as being “connected” to another element, the element can be “directly connected” to the other element or “indirectly connected” to the other element with other intervening element(s). Further, when a certain part “includes” a certain component, it does not exclude cases in which other components are included unless otherwise defined.

Hereinafter, exemplary embodiments of the present invention will be described in detail with reference to the accompanying drawings.

The exemplary embodiments of the present invention relate to a touch detection method for improving touch sensitivity by controlling parasitic capacitance.

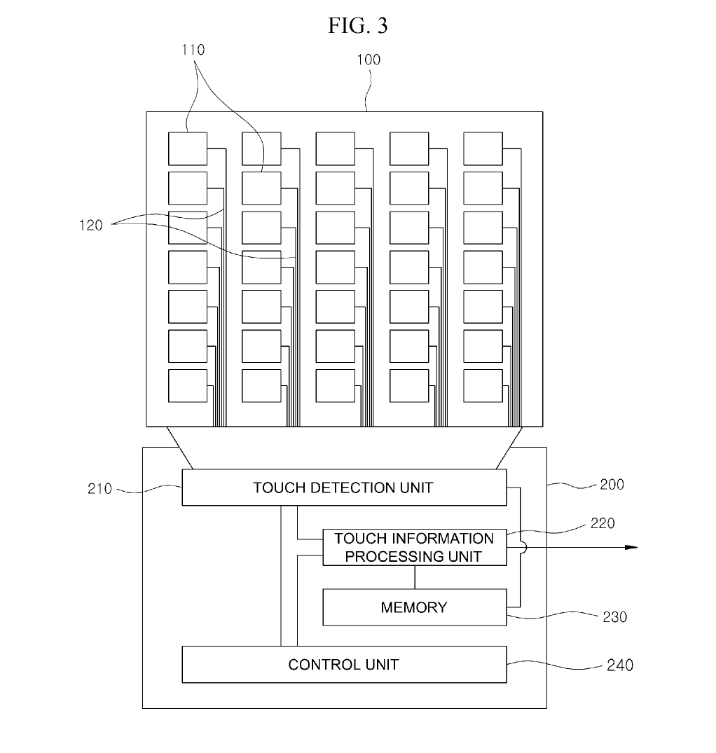

FIG. 3 is a view showing a structure of a touch detection apparatus according to an exemplary embodiment of the present invention.

Referring to FIG. 3, the touch detection apparatus includes a touch panel 100 and a driving device 200.

The touch panel 100 includes a plurality of sensor pads 110 and a plurality of signal wires 120 connected to the sensor pads 110.

For example, the plurality of sensor pads 110 may have a rectangular shape or a rhombus shape, however, they may have a different shape. The plurality of sensor pads 110 may have a regular polygon shape. The sensor pads 110 may be arranged in a matrix form of adjacent polygons.

The driving device 200 may include a touch detection unit 210, a touch information processing unit 220, a memory 230, and a control unit 240, and may be implemented using one or more integrated circuits (IC).

The touch detection unit 210, the touch information processing unit 220, the memory 230, and the control unit 240 may be separated from each other, or implemented by integrating two or more of the components.

The touch detection unit 210 may include a plurality of switches and a plurality of capacitors, which are connected to the sensor pads 110 and the signal wires 120, receive a signal from the control unit 240, drive circuits for touch detection, and output a voltage corresponding to a result of the touch detection. Further, the touch detection unit 210 may include an amplifier and an analog-digital converter, convert, amplify, or digitize a difference of voltage changes of the sensor pad 110, and then store the digitized voltage in the memory 230.

The touch information processing unit 220 processes the digitized voltage stored in the memory 230 and then generates necessary information such as whether the touch has occurred or not, an touch area, touch coordinates, etc.

The memory 230 stores the digitized voltage based on the difference of the voltage changes which are detected from the touch detection unit 210, predetermined data which is used for touch detection, area calculation, and touch coordinate calculation, or data received in real time.

The control unit 240 may control the touch detection unit 210 and the touch information processing unit 220, may include a micro control unit (MCU), and perform a defined signal process through firmware.

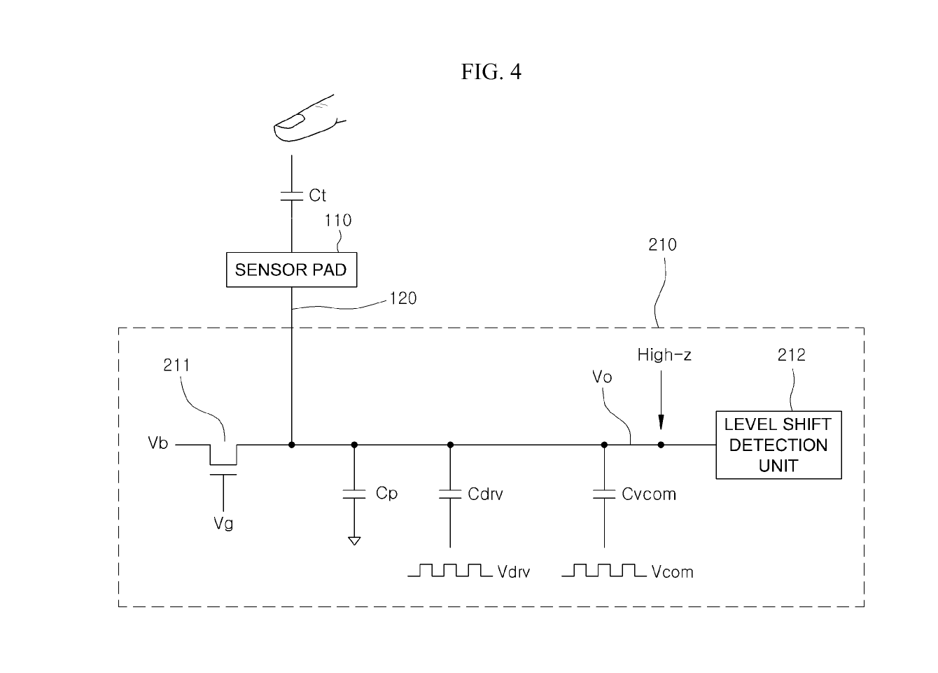

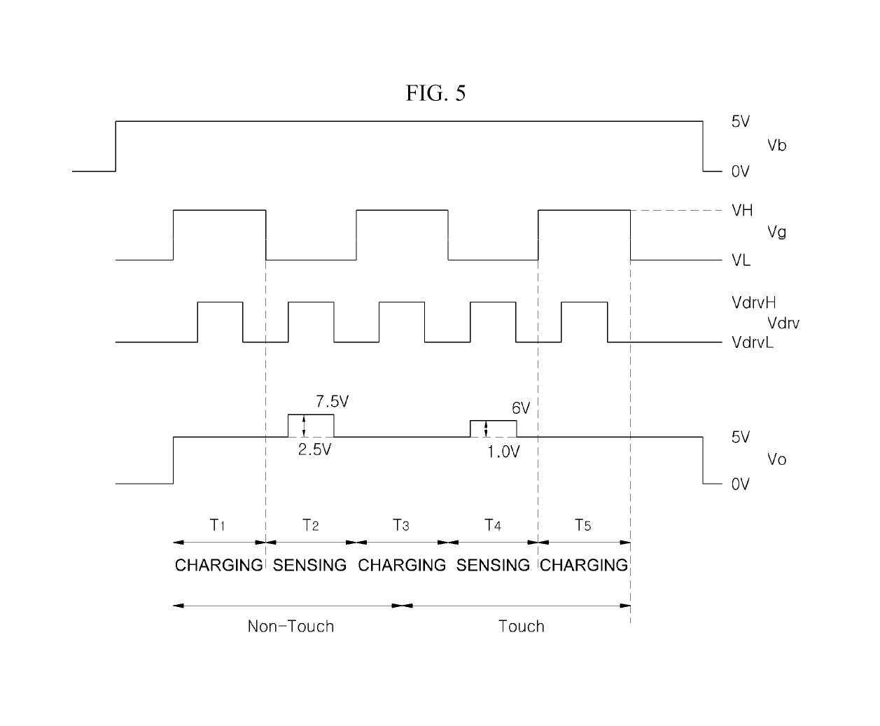

Operation of the touch panel and the touch detection unit 210, which are shown in FIG. 3 will be described in detail with reference to FIGS. 4 and 5.

FIG. 4 is a circuit diagram illustrating a touch detection unit according to an exemplary embodiment of the present invention, and FIG. 5 is a waveform diagram illustrating a touch detection unit according to the exemplary embodiment of the present invention.

Referring to FIG. 4, the touch detection unit 210 is connected to the sensor pad 110 through the signal wire 120, and includes a transistor 211 which performs a switching operation, a parasitic capacitor Cp, a driving capacitor Cdrv, a common voltage capacitor Cvcom, and a level shift detection unit 212.

The transistor 211, the parasitic capacitor Cp, the driving capacitor Cdrv, the common voltage capacitor Cvcom, and the level shift detection unit 212 may form a group per the sensor pad 110 and the signal wire 120. Hereinafter, the sensor pad 110, the signal wire 120, the transistor 211, the parasitic capacitor Cp, the driving capacitor Cdrv, the common voltage capacitor Cvcom, and the level shift detection unit 212 altogether are referred to as “a touch sensing unit.” The touch sensing unit includes a case in which the components are electrically connected to each other by a multiplexer.

Meanwhile, in the exemplary embodiment of the present invention, an electrical characteristic or a data value in the case in which a touch does not occur is referred as “a non-touch reference value.”

Hereinafter, reference numerals of the capacitor and its capacitance are the same for convenience.

For example, since the transistor 211 is a field effect transistor, a control signal Vg may be applied to a gate of the transistor 211, a charge signal Vb may be applied to a source of the transistor 211, and a drain of the transistor 211 may be connected to the signal wire 120. Alternatively, the source of the transistor 211 may be connected to the signal wire 120 and the charge signal Vb may be applied to the drain of the transistor 211. The control signal Vg and the charge signal Vb may be controlled by the control unit 240, and another device capable of performing a switching operation may be used instead of the transistor 211.

The parasitic capacitor Cp denotes a capacitor attached to the sensor pad 110, and is a type of parasitic capacitor formed by the sensor pad 110, the signal wire 120, etc. The parasitic capacitor Cp may include any parasitic capacitor generated by the touch detection unit 210, the touch panel 100, and an image display device.

The common voltage capacitor Cvcom is a capacitor formed between a common electrode (not shown) of the display device and the touch panel 100 when the touch panel 100 is mounted on the display device (not shown) such as a liquid crystal display (LCD). A common voltage Vcom such as a square-type wave, or the like is applied to the common electrode by the display device. Meanwhile, the common voltage capacitor Cvcom may also be included in the parasitic capacitor Cp as a type of parasitic capacitor. Hereinafter, unless additionally noted for the common voltage capacitor Cvcom, it will be described that the common voltage capacitor Cvcom includes the parasitic capacitor Cp.

The driving capacitor Cdry is a capacitor formed on a path which supplies an alternating voltage Vdry which alternates in each sensor pad 110 with a predetermined frequency. The alternating voltage Vdry applied to the driving capacitor Cdry is preferably a square-type wave. The alternating voltage Vdry may be a clock signal in which a duty ratio is the same, however, it may be different. The alternating voltage Vdry may be provided by an additional alternating voltage generating means, however, may use the common voltage Vcom.

Meanwhile, a touch capacitor Ct shown in FIG. 4 shows a capacitance formed between the sensor pad 110 and a touch input device such as a finger of a user, or the like when the user touches the sensor pad 110.

Referring to FIG. 5, the charge signal Vb and the control signal Vg are applied to the source and gate of the transistor 211, respectively.

First, a case (non-touch) in which the touch input device does not touch the sensor pad 110 will be described. For example, after the charge signal Vb is increased to 5 V, when the control signal Vg applied to the gate of the transistor 211 is increased from a low voltage VL to a high voltage VH, the transistor 211 is turned on and a charging interval T1 is started. Thus the sensor pad 110 is charged by the charge signal Vb of 5 V, and an output voltage Vo becomes the charge signal Vb. The parasitic capacitor Cp, the driving capacitor Cdrv, and the common voltage capacitor Cvcom are charged with electric charges by the charge signal Vb. Since the transistor 211 is turned on in the charging interval T1, the alternating voltage Vdry does not affect the output voltage Vo.

Then, when a sensing interval T2 is started while the control signal Vg is decreased from a high voltage VH to a low voltage VL, the transistor 211 is turned off, and the touch capacitor Ct, the parasitic capacitor Cp, the driving capacitor Cdrv, and the common voltage capacitor Cvcom are isolated in a charged state. In this case, in order to stably isolate the charged electric charges, an input of the level shift detection unit 212 may have high impedance.

As described above, the state in which the charged electric charges in the sensor pad 110, and the like are isolated is called a floating state. In this case, for example, when the alternating voltage Vdry applied to the driving capacitor Cdry is increased from 0 V to 5 V, a level of the output voltage Vo of the sensor pad 110 is momentarily increased, and when the alternating voltage Vdry is decreased again from 5 V to 0 V, the level of the output voltage Vo is momentarily decreased. In this case, the increase and decrease of the voltage level have different values according to the connected capacitance. A phenomenon in which the increase value and the decrease value of the voltage level are changed according to the connected capacitance is called “kick-back.”

When the sensor pad 110 is not touched, that is, when capacitors connected to the sensor pad 110 are only the driving capacitor Cdry and the parasitic capacitor Cp, a voltage change ΔVo1 of output voltages Vo by the capacitors Cdry and Cp is equal to the following Equation 1.

$$Δ Vo 1 = \pm ( VdrvH - VdrvL ) \frac{Cdrv}{Cdrv + Cp} \qquad [ Equation 1 ]$$

Here, VdrvH and VdrvL are a high voltage level and a low voltage level of the alternating voltage Vdrv, respectively. Since the ΔVo1 in Equation 1 corresponds to an electrical characteristic of the sensor pad 110 in which a touch does not occur, the ΔVo1 may set be to the above-described “the non-touch reference value.”

Next, a case in which the touch input device touches the sensor pad 110 will be described. When the touch occurs, the touch capacitor Ct is formed between the sensor pad 110 and the touch input device, and thus the touch capacitor Ct is added to a capacitor connected to the sensor pad 110 in addition to the driving capacitor Cdry and the parasitic capacitor Cp. In the same manner described above, a voltage change ΔVo2 of the sensor pad 110 due to the three capacitors Cdrv, Cp, and Ct in a sensing interval T4 through a charging interval T3 is equal to the following Equation 2.

$$Δ Vo 2 = \pm ( VdrvH - VdrvL ) \frac{Cdrv}{Cdrv + Cp + Ct} \qquad [ Equation 2 ]$$

Comparing Equation 1 and Equation 2, since Equation 2 is an equation in which the touch capacitor Ct is added to a denominator of Equation 2, the voltage change ΔVo2 in the case in which the touch occurs is smaller than the voltage change ΔVo1 in the case in which the touch does not occur, and a difference therebetween is changed according to the touch capacitor Ct. The difference (ΔVo2−ΔVo1) of the voltage change ΔVo before and after the touch is referred to as “level shift.”

Therefore, whether the level shift occurs or not may be checked by measuring the change ΔVo1 of the output voltage Vo in the sensor pad 110 when the touch does not occur and the change ΔVo2 of the output voltage Vo in the sensor pad 110 when the touch occurs, and thus whether the touch occurs or not may be detected.

The touch or the non-touch is clearly distinguished as the level shift value is great. However, when the sensor pad 110 is in a floating state, denominators of the equations have the parasitic capacitor Cp referring to the equations of the changes ΔVo1 and ΔVo2 of the output voltage Vo according to the applying of the alternating voltage Vdrv.

The embodiment of the present invention reduces an error range with respect to a size of the change ΔVo2 of the output voltage Vo in the sensor pad 110 according to the applying of the alternating voltage Vdry by controlling the value of the parasitic capacitor Cp when the touch occurs, improves touch sensitivity, and enhances tolerance against the noise.

First, a principle of generating the capacitance will be described as follows.

When a material having a dielectric constant (∈) surrounds conductors charged with different polarities, an amount (Q) of electric charge which is collected in the conductor according to a size of potential between the conductors is called a capacitance (C). That is, the capacitance (C) may be expressed by Equation 3.

C=∈*A/d [Equation 3]

Referring to Equation 3, the capacitance (C) is proportional to an area (A) of the conductor and is inversely proportional to a distance (d) between the conductors.

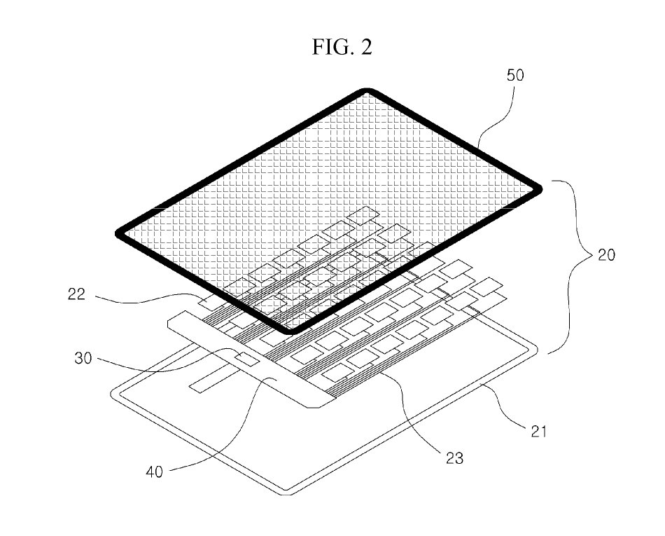

In the touch detection apparatus shown in FIG. 2, a dielectric material such as glass, OCA, or the like is present between the sensor pad and the signal wire, and the sensor pads or the signal wires may be insulated from each other through the dielectric material. Since the sensor pad and the signal wire are conductors, the touch detection apparatus has a structure including a number of conductors and the dielectric material which is present around the conductors, that is, a capacitor structure in which capacitance is formed.

Unwanted capacitance is formed due to an area of each conductor (the sensor pad or the signal wire), a distance between the conductors, and a dielectric constant (∈) of the dielectric material which is present between the conductors, and such capacitance becomes parasitic capacitor Cp.

Specifically, in a touch screen panel in which a plurality of sensor pads are densely disposed in rows and columns, since the conductors are very densely disposed and the number of conductors are distributed, an amount of the parasitic capacitor Cp generated by the disposition and the distribution is greatly increased. Therefore, the control of the parasitic capacitor Cp becomes a significant factor which affects performance related to the touch detection in the touch screen panel.

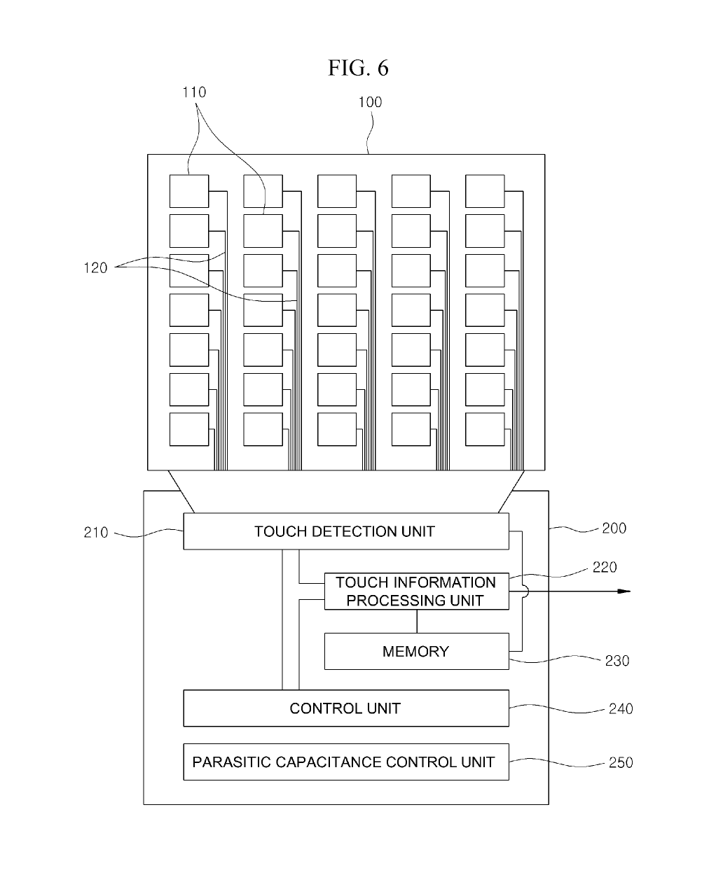

FIG. 6 is a view showing a touch detection apparatus according to an exemplary embodiment of the present invention.

Referring to FIG. 6, the driving device 200 of the touch detection apparatus according to the exemplary embodiment of the present invention may further include a parasitic capacitance control unit 250.

The parasitic capacitance control unit 250 according to the exemplary embodiment of the present invention applies an output voltage of a specific sensor pad which is to be an object of touch detection from among a plurality of sensor pads to another adjacent sensor pad having a signal wire adjacent to a signal wire of the specific sensor pad. Thus, the parasitic capacitance control unit 250 may reduce parasitic capacitance generated between the specific sensor pad which is to be an object of touch detection from among the plurality of sensor pads and another adjacent sensor pad.

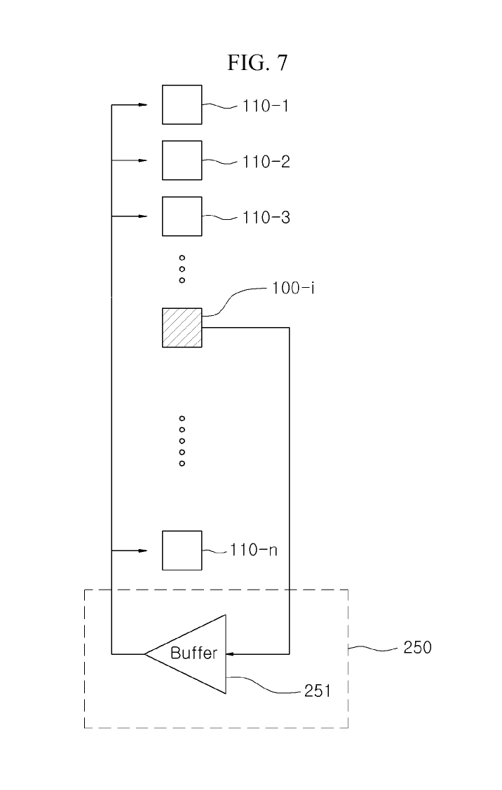

FIG. 7 is a view showing n sensor pads included in a column, and for describing a principle of reducing the parasitic capacitance. Referring to FIG. 7, the parasitic capacitance control unit 250 applies an output voltage of a sensor pad 110-i which is to be an object of touch detection from among a plurality of sensor pads included in the same column to the other sensor pads 110-1 to 110-n. Further, the parasitic capacitance control unit 250 may include a buffer 251 to prevent a short between the sensor pads 110-1 to 110-n which are separately disposed. That is, the output voltage of the sensor pad 110-i which is currently to be an object of touch detection may input to the buffer 251 and an output of the buffer 251 may be connected to other sensor pads 110-1 to 110-n.

The reason that the parasitic capacitance is reduced by the parasitic capacitance control unit 250 will be described as follows.

In a capacitor structure including two conductors and a dielectric material between the conductors, an amount (Q) of charge which is charged in the corresponding structure may be expressed by an equation Q=CV. Here, C is a capacitance value and V is a potential difference between both conductors.

In the above equation, when the voltage (V) converges close to zero, the amount (Q) of charge proportional to the potential difference between the conductors may converge close to zero. Since the capacitance (C) is proportional to charging ability of the charge, when the amount (Q) of charge which is charged is close to zero, the capacitance (C) formed by a relation between the conductors also converges close to zero.

Referring again to FIG. 7, the embodiment of the present invention uses the above principle. Thus, when the touch detection of a specific sensor pad 110-i is performed, the parasitic capacitor Cp which affects the touch detection is compensated to be close to ‘zero’ by controlling potentials of the sensor pad 110-i and the other sensor pads 110-1 to 110-n to be close to the same level.

For example, as shown in FIG. 7, when the output voltage of the sensor pad 110-i which is currently to be an object of touch detection from among sensor pads included in the same column is applied to the other sensor pads 110-1 to 110-n through the buffer 251 of the parasitic capacitance control unit 250, a potential difference between the sensor pad 110-i and the other sensor pads 110-1 to 110-n is minimized. Thus, the parasitic capacitance generated by the relation between the sensor pads may be effectively reduced.

Meanwhile, although the output voltage of the sensor pad 110-i is applied to the other sensor pads 110-1 to 110-n included in the same column with the sensor pad 110-i which is to be an object of touch detection, it is not limited thereto, and the output voltage of the sensor pad 110-i may be applied to other sensor pads included in the same row in the plurality of sensor pads 110.

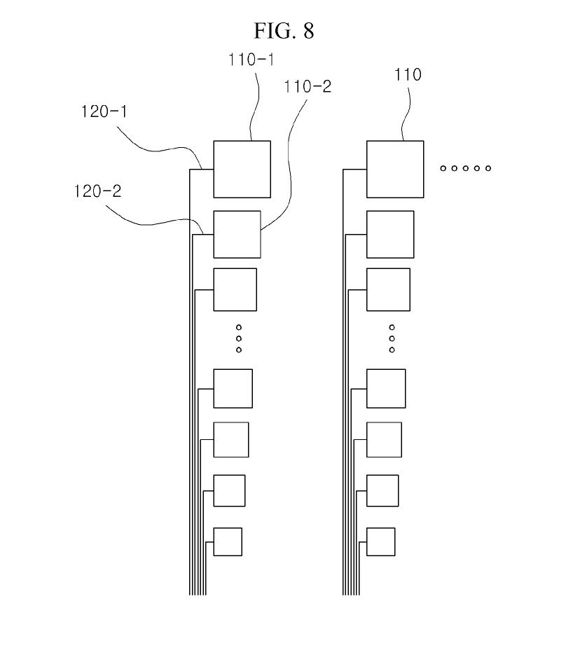

FIG. 8 is a view simply showing a touch detection apparatus in which a plurality of sensor pad columns including a plurality of sensor pads are included, and a view showing an arrangement of the sensor pads and signal wires connected to the sensor pads.

A size of the parasitic capacitance Cp, which is generated between the sensor pad 110 and the signal wire 120 connected to the sensor pad 110, is increased in a range in which the density of electric flux is high. As described above, since the size of the capacitance is increased as a distance between the conductors is smaller, the parasitic capacitance Cp is largely generated by a relation between the signal wires of the adjacent sensor pads.

Referring to FIG. 8, the signal wires 120 of the sensor pads 110, which are in the same column, are very closely disposed. For example, referring to a relation between a first sensor pad 110-1 and a second sensor pad 110-2, which are included in the same column, a first signal wire 120-1 connected to the first sensor pad 110-1 and a second signal wire 120-2 connected to the second sensor pad 110-2 are very closely and adjacently disposed side by side, and a total length of the adjacently disposed sensor pads is a distance between the second sensor pad 110-2 and the driving device 200 (see FIG. 6). Meanwhile, referring to a relation between the sensor pads which are included in the different columns compared to the above-described relation, since a distance between the signal wires 120 connected to each sensor pad 110 is increased, the parasitic capacitance Cp is formed to be relatively small.

That is, the parasitic capacitance Cp generated between the sensor pads included in the same column in which the signal wires 120 of the sensor pads 110 are adjacent to each other is relatively much greater than the parasitic capacitance Cp generated between the sensor pads included in different columns in which the signal wires 120 of the sensor pads 110 are distant from each other.

Therefore, in order to minimize the parasitic capacitance Cp formed between the adjacent sensor pads 110 in the embodiment of the present invention, an output voltage of the sensor pad 110 which is to be an object of touch detection is applied to another sensor pad 100 having a signal wire that is adjacent to the signal wire of the corresponding sensor pad 110.

Meanwhile, a size of the parasitic capacitance Cp between the sensor pads 110 is increased as the corresponding sensor pad 110 is disposed farther from the driving device 200 (see FIG. 6). Because lengths of the signal wires 120 connected to the corresponding sensor pad 110 and the sensor pad 110 that is adjacent to the corresponding sensor pad 110, respectively, that is, lengths of which the signal wires 120 connected to the sensor pads 110, respectively, are disposed side by side, are increased as the corresponding sensor pad 110 is disposed farther from the driving device 200.

When the touch detection is performed, a size of a touch capacitance Ct generated between a touch means (e.g., a finger, etc.) and the sensor pad 110 is checked and a touch area thereof is also detected. In order to detect the accurate touch area, the size of the touch capacitance Ct should be accurately detected. Therefore, it is preferable that the size of the touch capacitance Ct is not relatively affected by the size of the parasitic capacitance Cp.

As described above, since the relatively large parasitic capacitance Cp is formed in a relation between the sensor pads 110 which are disposed farther from the driving device 200, it is preferable that the touch area is large as the sensor pad 110 is disposed farther from the driving device 200 in order to further reduce these effects as shown in FIG. 8.

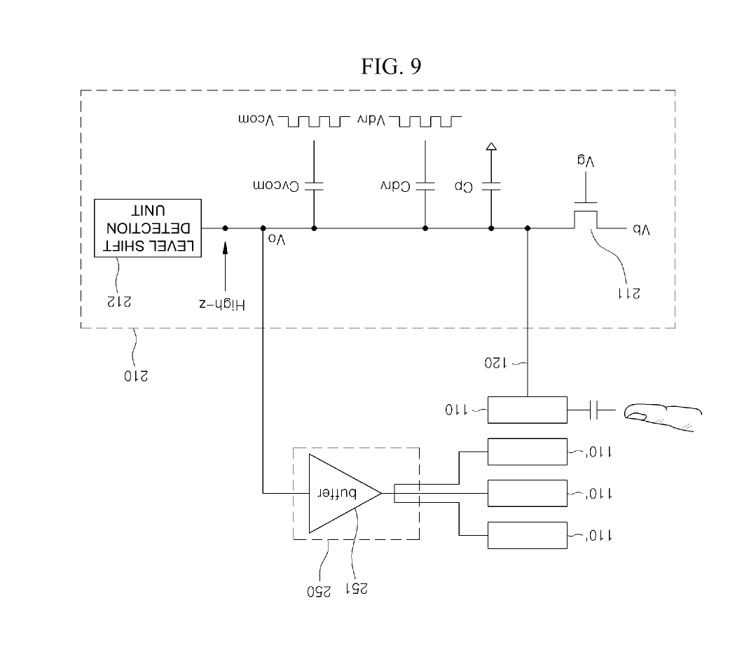

FIG. 9 is a simple circuit diagram of a touch detection apparatus according to an exemplary embodiment of the present invention.

Referring to FIG. 9, an output voltage Vo of a sensor pad 110 in a touch detection unit 210 is input to other sensor pads 110′ having signal wires that are adjacent to a signal wire of a specific sensor pad through a buffer 251 of a parasitic capacitance control unit 250. More specifically, an input of the buffer 251 may be connected to an output of the sensor pad 110 which is currently selected to be an object of touch detection and an output of the buffer 251 may be connected to each of other sensor pads 110′. The buffer 251 may be implemented as a buffer amplifier to have functions of preventing a short between the sensor pad 110 which is currently to be an object of touch detection and other sensor pads 110′, controlling signals, preventing interference, etc. In this case, since a potential between the sensor pads should be at the same level by applying the output voltage Vo of the sensor pad 110 which is to be an object of touch detection to other sensor pads 110′, a gain of the buffer amplifier should be one, however, this may be changed as needed. That is, the gain of the buffer 251 included in the parasitic capacitance control unit 250 may be changed to maintain a potential difference between the sensor pads 110 close to ‘0.’

A part that contributes most significantly to the parasitic capacitance Cp, that is, the parasitic capacitance Cp formed according to a relation between adjacent sensor pads may be reduced to a minimum through the parasitic capacitance control unit 250.

Since descriptions for other components of the touch detection unit 210 and touch detection operations are the same as descriptions described with reference to FIG. 4, those will be omitted.

Conventionally, all sensor pads 110′ including the sensor pad 110 which is to be an object of touch detection have been set as a group in any one state of floating, ground, and pre-charge.

However, according to the embodiment of the present invention, an output voltage Vo of a specific sensor pad 110 which is to be an object of touch detection is applied to other sensor pads 110′ having signal wires that are adjacent to the signal wire of the specific sensor pad 110 through the parasitic capacitance control unit 250. Therefore, the sensor pad 110 which is to be an object of touch detection and all of other sensor pads 110′ may be in a floating state. Further, the remaining sensor pads which do not include in the sensor pad 110 and the other sensor pads 110′ may be set in any one state of floating, ground, and pre-charge as in the conventional manner.

Meanwhile, the parasitic capacitance control unit may control the parasitic capacitance to be present between the sensor pads 110 in a different manner from the above-described manner.

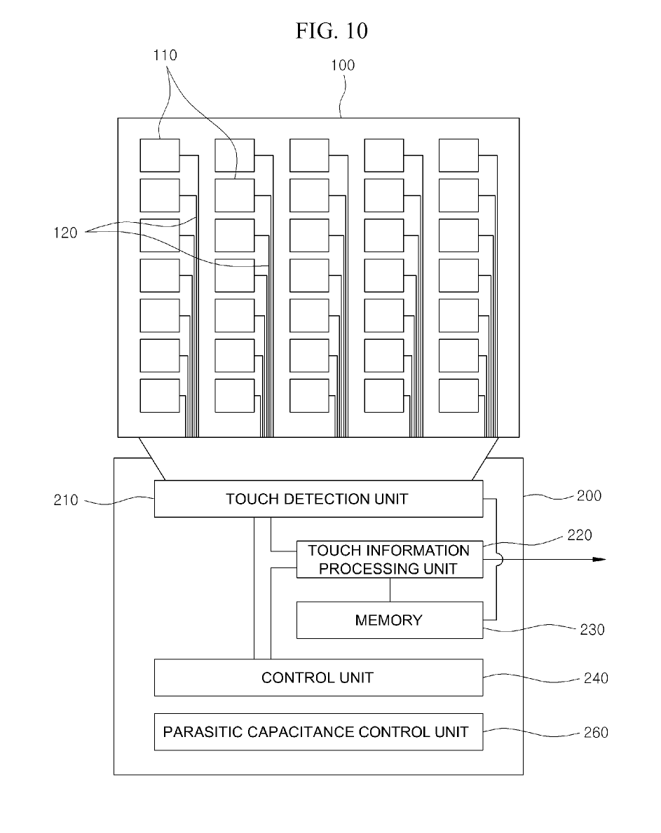

FIG. 10 is a view showing a touch detection apparatus according to another exemplary embodiment of the present invention.

Referring to FIG. 10, a driving device 200 of the touch detection apparatus according to the exemplary embodiment of the present invention may further include a parasitic capacitance control unit 260.

With respect to a specific sensor pad which is currently to be an object of touch detection from among a plurality of sensor pads 110, the parasitic capacitance control unit 260 applies an output voltage of the specific sensor pad, which is detected in a first frame to another sensor pad connected to a signal wire that is adjacent to a signal wire of the specific sensor pad when the touch detection of the specific sensor pad is performed in a second frame. Thus, the parasitic capacitance control unit 260 may control parasitic capacitance generated between the specific sensor pad which is to be an object of touch detection from among the plurality of sensor pads 110 and another adjacent sensor pad. Here, the frame means a cycle in which voltage values of the plurality of sensor pads 110 are detected in order to detect a touch position.

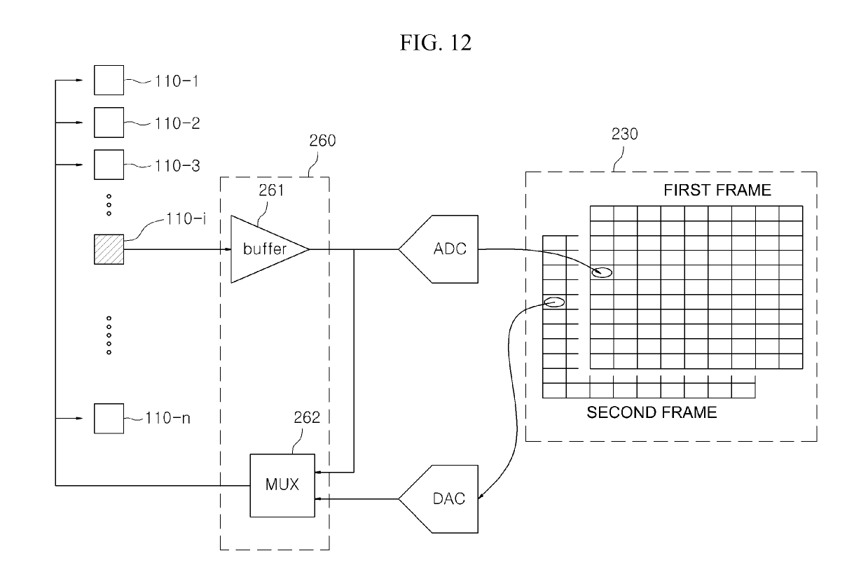

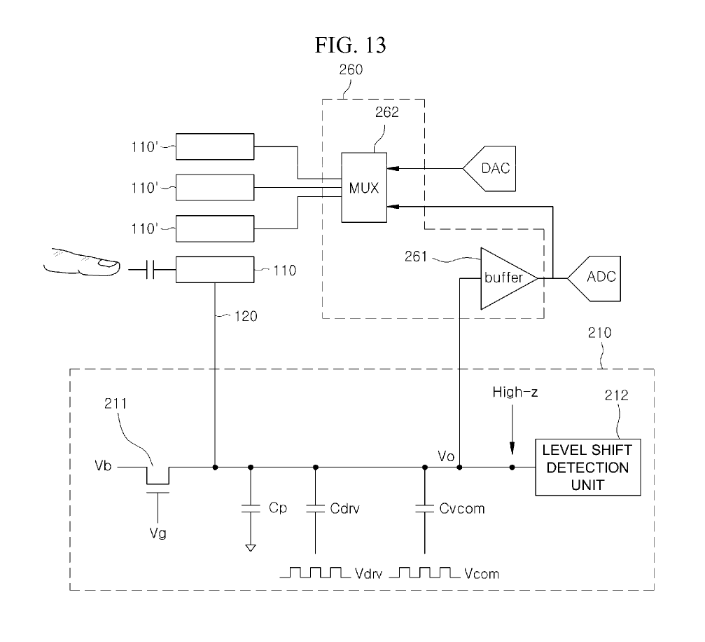

To this end, the parasitic capacitance control unit 260 may include a buffer 261 (see FIG. 12) and a multiplexer 262 (see FIG. 12), and descriptions thereof will be described below with reference to FIGS. 12 and 13.

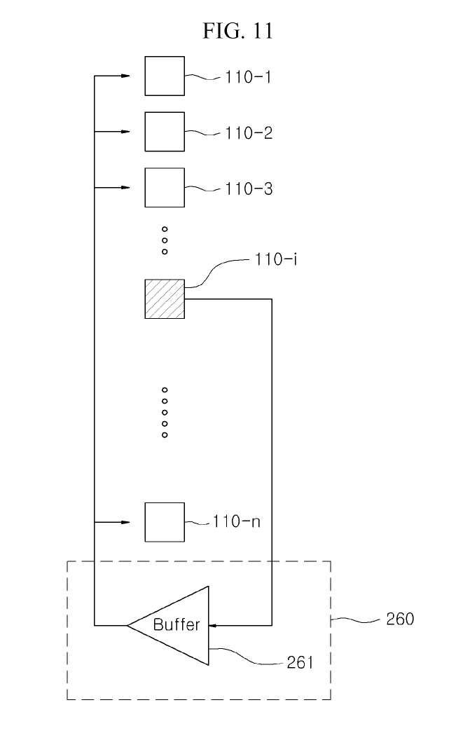

FIG. 11 is a view showing n sensor pads included in a column, and a view for describing a principle of controlling parasitic capacitance.

The parasitic capacitance control unit 260 may include the buffer 261 for preventing a short between the sensor pads 110-1 to 110-n which are separately disposed.

In a capacitor structure which includes two conductors and a dielectric material between the conductors, an amount (Q) of charge charged in the corresponding structure is the equation Q=CV as described above. In this equation, when a capacitance (C) is increased, a voltage (V), that is, a potential difference between the two conductors is reduced to a state in which the amount (Q) of charge is not increased or decreased.

Referring again to FIG. 11, the embodiment of the present invention uses the above principle. Thus, when the touch detection of a specific sensor pad 110-i is performed, an output voltage of the specific sensor pad 110-i in a previous frame is input to sensor pads 110-1 to 110-n, which are adjacent the specific sensor pad 110-i, through the buffer 261 in a current frame, and thus a capacitance between the output voltage of the specific sensor pad 110-i and the sensor pads 110-1 to 110-n is generated. Therefore, a range of a change of the output voltage value of the specific sensor pad 110-i is reduced.

More specifically, a case in which an output voltage of the specific sensor pad 110-i detected in the first frame is 2 V and an output voltage of the specific sensor pad 110-i detected in a second frame is 0 V will be described as follows.

When the output voltage of the specific sensor pad 110-i detected in the first frame, 2 V, is applied to the other sensor pads 110-1 to 110-n in the case of the touch detection of the specific sensor pad 110-i in the second frame, the output voltage of the specific sensor pad 110-i detected in the second frame is 0 V, however, the voltage of 2 V is applied to the other sensor pads 110-1 to 110-n. Thus, a potential difference between the specific sensor pad 110-i and the other sensor pads 110-1 to 110-n is generated, and thus capacitance (C) is generated. In this case, since the capacitance (C) is neither newly generated nor removed, the voltage (V) is reduced when the capacitance (C) is generated and increased in a uniform capacitance (C). In this case, the voltage (V) is a potential difference between the output voltage of the specific sensor pad 110-i detected when the touch detection of the specific sensor pad 110-i in the second frame is performed and the output voltage of the specific sensor pad 110-i detected in the first frame. Therefore, the potential difference between the output voltage of the specific sensor pad 110-i detected in the first frame and the output voltage of the specific sensor pad 110-i detected when the touch detection of the specific sensor pad 110-i in the second frame is performed is reduced.

That is, an error range of the value between the output voltages of the specific sensor pad detected in each frame is reduced in the case in which the output voltage of the specific sensor pad 110-i, which is detected in the previous frame is applied to other sensor pads when the touch detection of the specific sensor pad 110-i in the current frame is performed when compare to the case in which the output voltage of the specific sensor pad 110-i detected in the current frame is applied to other sensor pads, and thus touch sensitivity may be improved.

FIG. 12 is a view showing an example of a parasitic capacitance control unit of a touch detection apparatus according to another exemplary embodiment of the present invention.

Referring to FIG. 12, the parasitic capacitance control unit 260 applies an output voltage of a specific sensor pad 110-i which is to be an object of touch detection from among a plurality of sensor pads 110 detected in the first frame to other sensor pads 110-1 to 110-n in the case of the touch detection of the specific sensor pad 110-i in the second frame.

Further, the parasitic capacitance control unit 260 may include a buffer 261 and a multiplexer 262. In this case, the buffer 261 is for preventing a short between the sensor pads 110-1 to 110-n which are separately disposed, and the multiplexer 262 is for selecting the output voltage of the specific sensor pad 110-i applied to the other sensor pads 110-1 to 110-n. More specifically, the output voltage of the specific sensor pad 110-i which is to be an object of touch detection may be input to the buffer 261, an output of the buffer 261 may be connected to an input of the multiplexer 262, and an output of the multiplexer 262 may be connected to the other sensor pads 110-1 to 110-n. In this case, the multiplexer 262 may select one of the output voltage of the specific sensor pad 110-i detected in the first frame and the output voltage of the specific sensor pad 110-i detected in the second frame, and then selectively apply the selected output voltage to the other sensor pads 110-1 to 110-n.

The multiplexer 262 may apply the output voltage of the specific sensor pad 110-i detected in the first frame to the other sensor pads 110-1 to 110-n when the touch detection of the specific sensor pad 110-i in the second frame is performed. However, the multiplexer 262 may apply the output voltage of the specific sensor pad 110-i detected in the second frame to the other sensor pads 110-1 to 110-n when the touch detection of the specific sensor pad 110-i in the second frame is performed under a predetermined condition. For example, the multiplexer 262 may apply the output voltage of the specific sensor pad 110-i detected in the second frame to the other sensor pads 110-1 to 110-n when the touch detection of the specific sensor pad 110-i in the second frame is performed in the case in which the output voltage of the specific sensor pad 110-i detected in the second frame is greater than a reference value for the touch detection. In this case, the reference value may be set to a value of the output voltage of the specific sensor pad 110-i capable of detecting the touch when the touch occurs in advance.

That is, when a difference between the output voltage of the specific sensor pad 110-i detected in the first frame and the output voltage of the specific sensor pad 110-i detected in the second frame is greater than a threshold, the multiplexer 262 may input the output voltage of the specific sensor pad 110-i detected in the second frame instead of that of the first frame to the sensor pads 110-1 to 110-n which are around the specific sensor pad 110-i when the touch detection of the specific sensor pad 110-i is performed. Since this denotes changes of states from touch to non-touch or from non-touch to touch between the first frame and the second frame, there is no need to reduce a voltage difference between the output voltages of the specific sensor pad 110-i detected in both frames.

Further, the multiplexer 262 may apply the output voltage of the specific sensor pad 110-i detected in the first frame to the other sensor pads 110-1 to 110-n in the case in which the first frame is an initial frame when the touch detection of the specific sensor pad 110-i in the first frame is performed. Since the output voltage of the specific sensor pad 110-i detected in the previous frame does not exist when the first frame is an initial frame, the multiplexer 262 applies the output voltage of the specific sensor pad 110-i detected in the first frame through the buffer 261. Thus, parasitic capacitance generated by a relation between the sensor pads is reduced in the first frame, and thus an error caused when the touch detection is performed may be prevented. More specifically, since the voltage (V) is converged to 0 V in the equation Q=CV, the capacitance (C), that is, the parasitic capacitance between the specific sensor pad 110-i and the other sensor pads 110-1 to 110-n, is reduced. Therefore, the voltage change ΔVo2 calculated through Equation 2 is increased, and thus early touch detection accuracy may be improved.

Meanwhile, although a method in which one of the output voltages of the specific sensor pad 110-i detected in the first frame and in the second frame is selected through the multiplexer 262 is described, it is not limited thereto. The output voltage of the specific sensor pad 110-i may be stored in a memory 230, and then may be input to the multiplexer 262. That is, the output voltage of the specific sensor pad 110-i may be stored in the memory 230 (see FIG. 3) or the output voltage of the specific sensor pad 110-i stored in the memory 230 may be input to the multiplexer 262. For example, the output voltage of the specific sensor pad 110-i detected in the first frame is converted from digital to analog and stored in the memory 230 in advance, the output voltage of the specific sensor pad 110-i detected in the first frame is input to the multiplexer 262 when the touch detection of the specific sensor pad 110-i in the second frame is performed by converting from digital to analog, and thus may be applied to the other sensor pads 110-1 to 110-n. In this case, the output voltage of the specific sensor pad 110-i detected in the second frame may be stored in the memory 230 by converting from digital to analog.

FIG. 13 is a simple circuit diagram of a touch detection apparatus according to another exemplary embodiment of the present invention.

Referring to FIG. 13, with respect to a specific sensor pad 110 which is currently selected to be an object of touch detection in a touch detection unit 210, an output voltage Vo of the sensor pad 110 detected in a first frame is input to other sensor pads 110′ connected to signal wires that are adjacent to a signal wire of the specific sensor pad when the touch detection of the specific sensor pad is performed in a second frame through the buffer 261 and the multiplexer 262 of the parasitic capacitance control unit 260. More specifically, an input of the buffer 261 may be connected to an output of the specific sensor pad 110 which is currently selected to be an object of touch detection, an output of the buffer 261 may be connected to an input of the multiplexer 262, and an output of the multiplexer 262 may be connected to the other sensor pads 110-1 to 110-n, respectively.

The buffer 261 may be implemented as a buffer amplifier to have functions of preventing a short between the sensor pad 110 which is to be an object of touch detection and the other sensor pads 110′, controlling signals, preventing intervention, etc. In this case, since the output voltage Vo of the sensor pad 110 which is to be an object of touch detection detected in the first frame should be applied to other sensor pads 110′ when the touch detection of the sensor pad 110 is performed in the second frame, a gain of the buffer amplifier should be one, however, this may be changed as needed. That is, the gain of the buffer 261 included in the parasitic capacitance control unit 260 may be changed to reduce a potential difference between the sensor pad 110 in the first frame and the second frame.

A part that contributes most significantly to the parasitic capacitance Cp, that is, the parasitic capacitance Cp formed according to a relation between adjacent sensor pads may be controlled through the parasitic capacitance control unit 260, and thus touch sensitivity may be improved by reducing an error range with respect to the output voltage value of the sensor pad 110 when the touch detection is performed.

According to the embodiment of the present invention, the parasitic capacitance generated between adjacent sensor pads by the parasitic capacitance control unit 260 may be suppressed or generated. Thus, the parasitic capacitance may be controlled, and thus sensitivity of the touch detection may be improved by reducing an error range with respect to the output voltage value of the sensor pad 110.

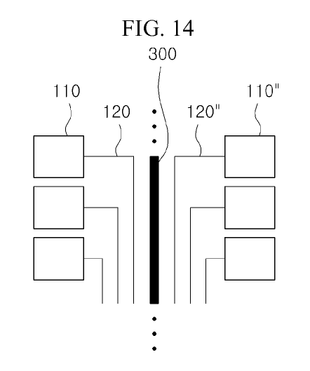

Meanwhile, referring to FIG. 14, a dummy line 300 which is formed between a column including a plurality of sensor pads and adjacent column may be further included in the touch detection apparatus according to the embodiment of the present invention.

The dummy line 300 reduces parasitic capacitance Cp generated by a relation between a specific sensor pad 110 and a sensor pad 110″ included in the adjacent column.

More specifically, signal wires 120 connected to the sensor pads 110 included in a specific column may generate the parasitic capacitance Cp by a relation with a signal wire 120″ connected to the sensor pad 110″ included in a specific column. Specifically, referring to an arrangement of the signal wires 120, since the sensor pad 110 connected to the driving device 200 (see FIGS. 6 and 10) is very close to the signal wire 120″ that is connected to the sensor pad 110″ in the adjacent column as the sensor pad 110 is farther from the driving device 200, a more severe parasitic capacitance Cp is generated by a relation with the sensor pad 110″ included in the adjacent column.

The dummy line 300 may be formed to reduce the parasitic capacitance Cp generated by the relation between adjacent columns.

The dummy line 300 may extend between the columns in a direction farther from the driving device 200 (see FIGS. 6 and 10), that is, in a column direction.

No signal is applied to the dummy line 300 disposed between the columns (maintain in an isolate state), however, a driving signal received from the driving device 200 (see FIGS. 6 and 10) may be applied.

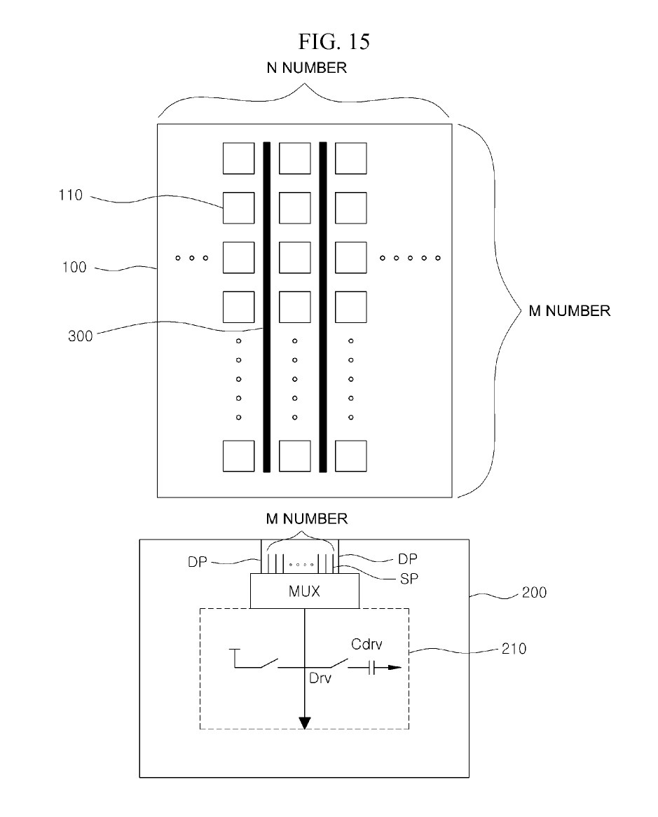

FIG. 15 is a view showing a configuration of a touch detection apparatus according to an exemplary embodiment of the present invention, and a view for describing a principle of applying a driving signal to the dummy line 300 disposed between the columns.

Referring to FIG. 15, when a plurality of sensor pads 110 are disposed in an N×M matrix form in a touch panel 100, N multiplexers MUX are included in a touch detection unit 210.

That is, one multiplexer MUX is included in one column, and the multiplexer MUX selects one of M sensor pads 110 included in one column. To this end, the multiplexer MUX includes M sensor pad select pins SP, and the M sensor pad select pins SP are connected to the M sensor pads 110 included in one column, respectively, through signal wires. Touch detection is performed by applying the driving signal to the sensor pad 110 selected by the multiplexer MUX. In this case, the corresponding driving signal may also be applied to the dummy line 300 disposed at right side and left side of the column including the sensor pad 110 which is to be an object of touch detection. To this end, the multiplexer MUX may further include a dummy line driving pin DP. The dummy line driving pin DP enables the driving signal to be applied to the dummy line 300 when the driving signal for touch detection of the sensor pad 110 is applied. That is, the dummy line 300 may be connected to the dummy line driving pin DP included in the multiplexer MUX of the touch detection unit 210.

When the touch detection of a specific sensor pad 110 is performed, a sensor pad included in a column adjacent to the sensor pad 110 may have a different potential, and thus parasitic capacitance Cp may be generated by a relation between the sensor pads included in adjacent columns. However, as shown in FIG. 15, in the case in which the touch detection of the specific sensor pad 110 is performed, when the driving signal is also applied to the dummy line 300, the dummy line 300 which is a conductor most adjacent to the corresponding sensor pad 110 has substantially the same potential, and thus the parasitic capacitance Cp generated according to a relation between the columns may be prevented.

The above description of the invention is only exemplary, and it will be understood by those skilled in the art that various modifications can be made without departing from the scope of the present invention and without changing essential features. Therefore, the above-described embodiments should be considered in a descriptive sense only and not for purposes of limitation. For example, each component described as a single type may be dispersed, on the contrary, components described as a dispersed types may perform as a combined type thereof.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

1. A touch detection apparatus for a touch panel, including a plurality of sensor pads and signal wires connected to the plurality of sensor pads, respectively, comprising;
a parasitic capacitance control unit configured to control the parasitic capacitance generated between a specific sensor pad which is to be an object of touch detection from among the plurality of sensor pads and another adjacent sensor pad,
wherein the parasitic capacitance control unit enables an output voltage of the specific sensor pad to be applied to another sensor pad connected to the signal wire that is adjacent to the signal wire of the specific sensor pad.

2. The apparatus of claim 1, wherein the parasitic capacitance control unit enables the output voltage of the specific sensor pad to be applied to another sensor pad when the specific sensor pad is detected.

3. The apparatus of claim 2, wherein the parasitic capacitance control unit comprises a buffer, wherein an input end of the buffer is connected to an output end of the specific sensor pad and an output end of the buffer is connected to another sensor pad, respectively.

4. The apparatus of claim 1, wherein the parasitic capacitance control unit enables one of the output voltages of the specific sensor pad, which are detected from a first frame and a second frame to be selectively applied to another sensor pad in the second frame.

5. The apparatus of claim 4, wherein the parasitic capacitance control unit comprises a buffer and a multiplexer,
wherein an input end of the buffer is connected to an output end of the specific sensor pad, an output end of the buffer is connected to an input end of the multiplexer, and an output end of the multiplexer is connected to another sensor pad, respectively.

6. (canceled)

7. The apparatus of claim 4, wherein the parasitic capacitance control unit enables the output voltage of the specific sensor pad to be applied to another sensor pad in the first frame when the first frame is an initial frame.

8. The apparatus of claim 4, wherein the parasitic capacitance control unit enables the output voltage of the specific sensor pad to be applied to another sensor pad in the second frame when the output voltage of the specific sensor pad detected from the second frame is greater than a reference value for detecting the touch.

9. The apparatus of claim 1, wherein the plurality of sensor pads are disposed in row and column directions and a dummy line is formed between columns to suppress generation of parasitic capacitance between sensor pads included in adjacent columns disposed in the column direction.

10. The apparatus of claim 1, wherein the plurality of sensor pads has the greater area, the farther from a driving device which drives the sensor pads.

11. A touch detection method of a touch panel, including a plurality of sensor pads and signal wires connected to the plurality of sensor pads, respectively, comprising:
controlling a parasitic capacitance so that an output voltage of a specific sensor pad which is to be an object of touch detection from among the plurality of sensor pads is applied to another sensor pad connected to the signal wire that is adjacent to the signal wire of the specific sensor pad; and
detecting the touch based on a change difference of the output voltage of the specific sensor pad,
wherein the attenuation enables the output voltage of the specific sensor pad to be applied to another sensor pad having signal wire that is adjacent to the signal wire of the specific sensor pad when the specific sensor pad is detected.

12. The method of claim 11, wherein the controlling of the parasitic capacitance comprises enabling the output voltage of the specific sensor pad to be applied to another sensor pad when the specific sensor pad is detected.

13. The method of claim 11, wherein the controlling of the parasitic capacitance comprises selectively enabling one of the output voltages of the specific sensor pad, which are detected from a first frame and a second frame to be applied to another sensor pad in the second frame.

14. The method of claim 13, wherein the controlling of the parasitic capacitance comprises enabling the output voltage of the specific sensor pad to be applied to another sensor pad in the first frame when the first frame is an initial frame.

15. The method of claim 13, wherein the controlling of the parasitic capacitance comprises enabling the output voltage of the specific sensor pad to be applied to another sensor pad in the second frame when the output voltage of the specific sensor pad detected from the second frame is greater than a reference value for detecting the touch.
